(19) United States
(12) Patent Application Publication
(10) Pub. No.: US 2023/0154820 A1
(43) Pub. Date: May 18, 2023

(54) POWER SEMICONDUCTOR DEVICE AND POWER CONVERSION DEVICE

(71) Applicant: Mitsubishi Electric Corporation, Tokyo (JP)

(72) Inventors: Tomohisa YAMANE, Chiyoda-ku, Tokyo (JP); Takashi NISHIMURA, Chiyoda-ku, Tokyo (JP); Hiroshi KOBAYASHI, Chiyoda-ku, Tokyo (JP); Tatsushi MORISADA, Chiyoda-ku, Tokyo (JP); Masaru FUKU, Chiyoda-ku, Tokyo (JP)

(73) Assignee: Mitsubishi Electric Corporation, Tokyo (JP)

(21) Appl. No.: 17/798,079

(22) PCT Filed: Apr. 10, 2020
(86) PCT No.: PCT/JP2020/016078

§ 371 Date: Aug. 8, 2022

(51) Int. Cl. H01L 23/367; H01L 23/00

(52) U.S. Cl. CPC H01L 23/3672; H01L 24/48; H01L 24/32; H01L 24/73; H01L 2224/48091; H01L 2224/32225; H01L 2224/73265

(57) ABSTRACT

A power semiconductor device includes a power module unit, an adhesive sheet, a support member, and a flow prevention frame. The adhesive sheet is bonded to the power module unit. The support member is connected to the power module unit with the adhesive sheet therebetween. The flow prevention frame is sandwiched between the power module unit and the support member, and is placed around the adhesive sheet. The adhesive sheet has an outer peripheral surface adjoining an inner peripheral surface of the flow prevention frame. A value obtained by dividing a maximum value of the internal pressure on the outer peripheral surface by a minimum value of the internal pressure is less than or equal to 10.

### TECHNICAL FIELD

The present disclosure relates to a power semiconductor device and a power conversion device.

### BACKGROUND ART

Conventionally, a screw has been often used to connect and fix a power module and a support member to each other. In particular, in a case where heat dissipation is required, a fixing method with a screw using heat dissipation grease on a joint surface has been adopted. However, this method entails a problem of an increase in size because the screw fixing part is large. This method also entails a problem of deterioration in thermal resistance and reduction in insulation due to deterioration of grease.

In recent years, a method for joining a support member and a power module using an adhesive sheet having high adhesiveness has been applied. Particularly, when the support member is formed from a heat dissipation member, a heat dissipation adhesive sheet having high thermal conductivity is selected as the adhesive sheet. When the power module and the support member are not at the same potential, the adhesive sheet is required to have insulation. Therefore, a multifunctional material having heat dissipation, insulation, and adhesiveness may be selected as the adhesive sheet. As a result, it is possible to reduce the mounting area and the cost of the power semiconductor device.

As the adhesive sheet having the above characteristics, a thermally conductive resin composition obtained by combining an inorganic substance and a thermosetting resin is used, for example. When the power module and the support member are joined, a method for heating an uncured adhesive sheet and applying pressure to the adhesive sheet during curing is used. The inorganic substance is not involved in adhesiveness, and the thermosetting resin ensures adhesiveness. In many cases, voids are present in the thermosetting resin.

In order to uniformly join the power module and the support member, it is necessary to first heat the adhesive sheet, and at a timing when the viscosity of the thermosetting resin decreases, apply pressure thereto. The pressing force needs to be appropriately set in consideration of influences such as deformation of the power module, deformation of the support member, and irregularities of the joined surface due to application of pressure. When the pressing force is too low, a gap is generated between the power module or the support member and the adhesive sheet. In addition, voids originally present inside the adhesive sheet may remain and cause internal cracks. As a result, the bonding reliability may be lowered.

In addition, when the adhesive sheet is made of a multifunctional material having insulation and heat dissipation, the influence of voids in the adhesive sheet is more remarkable. Regarding insulation, partial discharge due to voids in the adhesive sheet causes a decrease in insulation reliability. The relationship between the void size and the partial discharge is based on Paschen's law Paschen's law. Specifically, the larger the void, the lower the insulation reliability. Similarly, regarding heat dissipation, the thermal conductivity of a portion where the void is present may be lowered.

Commonly, the power module is bonded to the upper surface of the adhesive sheet, and the support member is bonded to the lower surface of the adhesive sheet. The lateral face of the adhesive sheet is not bonded to the power module and the support member. When the adhesive sheet is bonded to the power module and the support member, the power module, the support member, and the adhesive sheet are pressurized in the vertical direction of the adhesive sheet. Since the lateral face of the adhesive sheet is open, almost no internal pressure is generated inside the adhesive sheet. To address this problem, Japanese Patent Laying-Open No. 2012-174965 (Patent Literature 1) discloses a sheet volume increase/decrease absorbing portion provided in a peripheral portion of an adhesive sheet.

### CITATION LIST

### Patent Literature

PTL 1: Japanese Patent Laying-Open No. 2012-174965

### SUMMARY OF INVENTION

### Technical Problem

As described in Patent Literature 1, it is considered that adhesiveness, heat dissipation, and insulation can be improved by providing a frame that defines an increase or decrease in volume of the adhesive sheet. However, in the technique disclosed in Patent Literature 1, a difference in an amount of flow of a thermosetting resin in the adhesive sheet occurs due to a difference in the distance from the center of pressure applied to the adhesive sheet to the inner peripheral surface of the sheet volume increase/decrease absorption portion. Therefore, a difference occurs in the internal pressure of the outer peripheral surface of the adhesive sheet.

Specifically, when the adhesive sheet is bonded to the power module and the support member, the adhesive sheet flows in the in-plane direction. The adhesive sheet includes, for example, ceramic, a thermosetting resin, and voids. The ceramic, the thermosetting resin, and the voids are considered as a liquid, the thickness direction of the adhesive sheet is considered as a flow path cross-sectional area, and the distance from the center of the adhesive sheet is considered as a flow path length. Applying hydrodynamics theory, when the adhesive sheet is rectangular, the corner portion of the adhesive sheet is the farthest from the center of the adhesive sheet. At the corner portion of the adhesive sheet, the flow path length is long, so that the fluid resistance increases. As a result, at the corner portion of the adhesive sheet, the liquid amount of the adhesive sheet is the smallest, so that the internal pressure is the lowest. When the internal pressure of the adhesive sheet is low, the number and size of voids remaining in the adhesive sheet increase, so that each of adhesiveness, heat dissipation, and insulation deteriorates. Therefore, the reliability of the power semiconductor device decreases.

The present disclosure has been accomplished in view of the above problems, and an object thereof is to provide a power semiconductor device capable of improving reliability.

### Solution to Problem

A power semiconductor device according to the present disclosure includes a power module unit, an adhesive sheet, a support member, and a flow prevention frame. The adhesive sheet is bonded to the power module unit. The support member is connected to the power module unit with the adhesive sheet interposed between the power module unit and the support member. The flow prevention frame is sandwiched between the power module unit and the support member, and is placed around the adhesive sheet. The adhesive sheet has an outer peripheral surface adjoining an inner peripheral surface of the flow prevention frame. A value obtained by dividing a maximum value of an internal pressure on the outer peripheral surface by a minimum value of the internal pressure is less than or equal to 10.

### Advantageous Effects of Invention

According to the power semiconductor device according to the present disclosure, it is possible to improve adhesiveness, heat dissipation, and insulation of the adhesive sheet by reducing the number and size of voids remaining in the adhesive sheet. As a result, the reliability of the power semiconductor device can be improved.

### BRIEF DESCRIPTION OF DRAWINGS

FIG. 1 is a schematic perspective view illustrating a configuration of a power semiconductor device according to a first embodiment.

FIG. 2 is a cross-sectional view taken along line II-II in FIG. 1.

FIG. 3 is a cross-sectional view taken along line III-III in FIG. 2.

FIG. 4 is a schematic cross-sectional view illustrating a manufacturing process of the power semiconductor device according to the first embodiment.

FIG. 5 is a schematic cross-sectional view illustrating a configuration of a power semiconductor device according to a second embodiment.

FIG. 6 is a schematic perspective view illustrating a configuration of a power semiconductor device according to a third embodiment.

FIG. 7 is a schematic perspective view illustrating a configuration of a power module of the power semiconductor device according to the third embodiment.

FIG. 8 is a cross-sectional view taken along line VIII-VIII in FIG. 6.

FIG. 9 is a cross-sectional view taken along line IX-IX in FIG. 8.

FIG. 10 is a schematic perspective view illustrating a configuration of a power semiconductor device according to a fourth embodiment.

FIG. 11 is a schematic perspective view illustrating a configuration of a support member of the power semiconductor device according to the fourth embodiment.

FIG. 12 is a cross-sectional view taken along line XII-XII in FIG. 10.

FIG. 13 is a cross-sectional view taken along line XIII-XIII in FIG. 12.

FIG. 14 is a schematic cross-sectional view illustrating a configuration of a power semiconductor device according to a fifth embodiment.

FIG. 15 is a schematic cross-sectional view illustrating a configuration of a power semiconductor device according to a sixth embodiment.

FIG. 16 is a schematic cross-sectional view illustrating a configuration of a power semiconductor device according to a seventh embodiment.

FIG. 17 is a schematic cross-sectional view illustrating a configuration of a power semiconductor device according to an eighth embodiment.

FIG. 18 is a cross-sectional view taken along line XVIII-XVIII in FIG. 17.

FIG. 19 is a schematic cross-sectional view illustrating a configuration of a power semiconductor device according to a ninth embodiment.

FIG. 20 is a cross-sectional view taken along line XX-XX in FIG. 19.

FIG. 21 is a block diagram illustrating a configuration of a power conversion system to which a power conversion device according to a tenth embodiment is applied.

### DESCRIPTION OF EMBODIMENTS

Embodiments of the present disclosure will be described below in detail. In the following description, the same or corresponding elements are denoted by the same reference numerals, and the redundant description thereof will not be repeated.

### First Embodiment

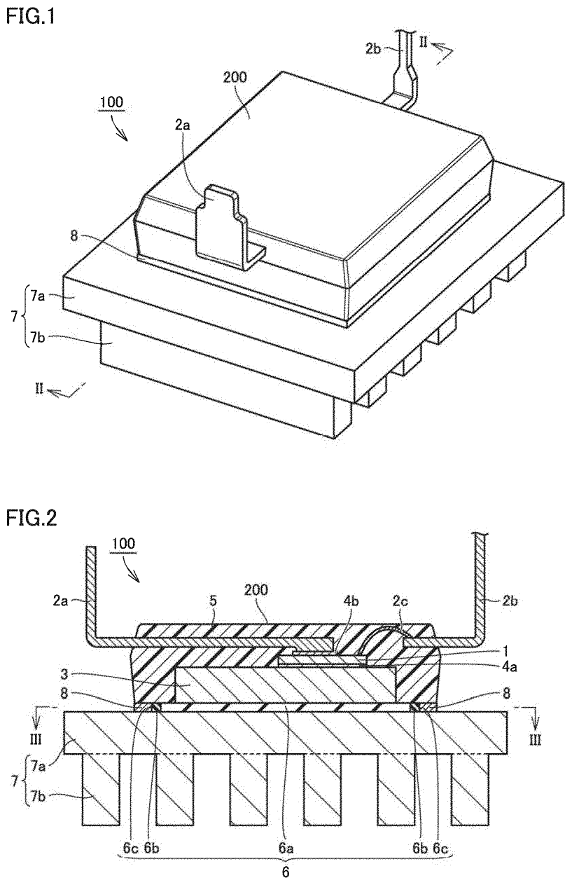

FIG. 1 is a schematic perspective view illustrating a configuration of a power semiconductor device according to a first embodiment. FIG. 2 is a cross-sectional view taken along line II-II in FIG. 1.

As illustrated in FIGS. 1 and 2, a power semiconductor device 100 according to the first embodiment mainly includes a power module unit 200, an adhesive sheet 6, a support member 7, and a flow prevention frame 8. Power module unit 200 mainly includes a power semiconductor element 1, a first metal wiring member 2a, a second metal wiring member 2b, a third metal wiring member 2c, a heat spreader 3, a first metal bonding member 4a, a second metal bonding member 4b, and a mold resin portion 5. Power semiconductor element 1 is sealed by mold resin portion 5. Power semiconductor element 1 is bonded to heat spreader 3 using first metal bonding member 4a. Power semiconductor element 1 is bonded to first metal wiring member 2a using second metal bonding member 4b.

First metal wiring member 2a and second metal wiring member 2b are made of, for example, solder or metal such as silver or aluminum. Power semiconductor element 1 is bonded to second metal wiring member 2b using third metal wiring member 2c. Third metal wiring member 2c is, for example, a wire made of aluminum, copper, or the like. Power semiconductor element 1 is, for example, a voltage-driven metal oxide semiconductor field effect transistor (MOSFET), insulated gate bipolar transistor (IGBT), diode, or the like. Power semiconductor element 1 is made of, for example, a semiconductor such as silicon, silicon nitride, gallium nitride, or silicon carbide. Power semiconductor element 1 is a main heat source in power module unit 200.

Each of first metal wiring member 2a and second metal wiring member 2b is molded with a part thereof being exposed to the outside of mold resin portion 5. Each of first metal wiring member 2a and second metal wiring member 2b serves as a connection portion with the outside. Support member 7 is, for example, a heat sink that diffuses heat generated by power semiconductor element 1 during operation to the outside. Support member 7 is made of metal such as aluminum or copper, for example. Support member 7 is connected to power module unit 200 with adhesive sheet 6 therebetween. Support member 7 includes, for example, a body portion 7a and a plurality of fins 7b. Since support member 7 has the plurality of fins 7b, heat dissipation is improved. A cooling solution may be put into support member 7 to cool support member 7. Support member 7 may be connected to a peripheral component such as a radiator (not illustrated). The cooling solution is, for example, water.

At least one surface of power module unit 200 is connected to support member 7 using adhesive sheet 6. For example, power module unit 200 may have a structure in which a part of heat spreader 3 having no insulating function is exposed from mold resin portion 5, and the exposed surface and support member 7 are connected by adhesive sheet 6 having insulation, adhesiveness, and heat dissipation. Power module unit 200 may have a structure in which an insulating substrate holding ceramic is used as heat spreader 3 which is partly exposed from mold resin portion 5, and the exposed surface and support member 7 are connected by adhesive sheet 6 having adhesiveness and heat dissipation. Power module unit 200 may have a structure in which all surfaces are sealed with a mold resin and any one of the surfaces is joined to support member 7 using adhesive sheet 6 having adhesiveness and heat dissipation.

Adhesive sheet 6 is bonded to power module unit 200. Adhesive sheet 6 is in contact with each of heat spreader 3 and mold resin portion 5, for example. Adhesive sheet 6 is, for example, a mixture of ceramic and a thermosetting resin. The ceramic is, for example, boron nitride. The thermosetting resin is, for example, an epoxy resin or a polyimide resin. Adhesive sheet 6 may be formed by simply mixing ceramic grains in a thermosetting resin, or may be formed by impregnating a ceramic skeleton with a thermosetting resin. The ceramic functions as a heat dissipation path. The thermosetting resin ensures adhesiveness. The ceramic and the thermosetting resin have insulating properties.

It is only sufficient that adhesive sheet 6 is made of a material having heat dissipation, insulation, and adhesiveness, and the material of adhesive sheet 6 is not limited to the above materials. Adhesive sheet 6 as described above generally contains voids within about a range of 1 vol % or more and 14 vol % or less, for example. There may be a possibility that adhesiveness, insulation, and heat dissipation of adhesive sheet 6 are deteriorated due to the voids.

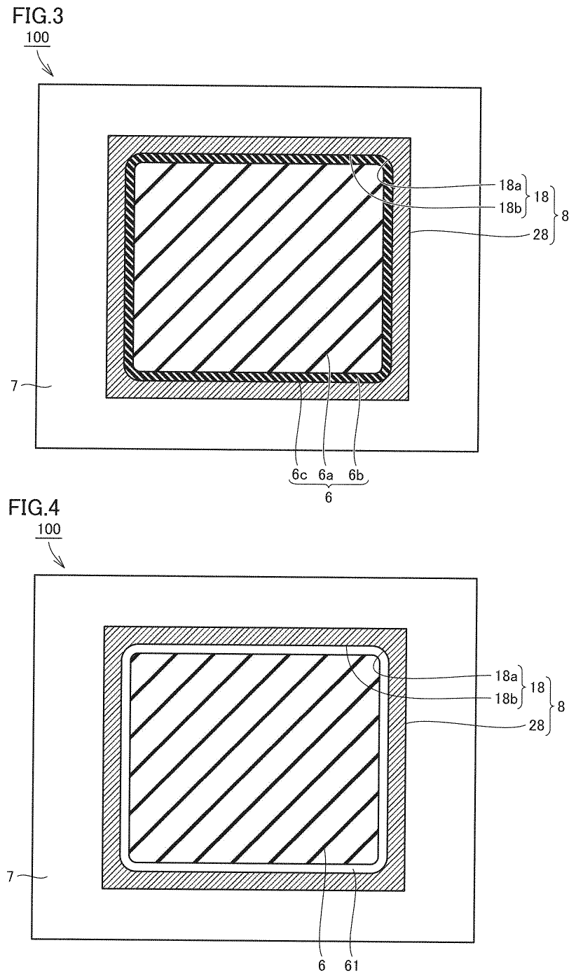

As illustrated in FIG. 2, flow prevention frame 8 is sandwiched between power module unit 200 and support member 7. Flow prevention frame 8 is placed around adhesive sheet 6. FIG. 3 is a cross-sectional view taken along line III-III in FIG. 2. As illustrated in FIG. 3, flow prevention frame 8 has an inner peripheral surface 18 and an outer wall surface 28. Outer wall surface 28 is located outside inner peripheral surface 18. Outer wall surface 28 surrounds inner peripheral surface 18. Adhesive sheet 6 has a central portion 6a, an outer peripheral portion 6b, and an outer peripheral surface 6c. Outer peripheral portion 6b is located outside central portion 6a. Outer peripheral portion 6b is continuous with central portion 6a. Outer peripheral portion 6b constitutes outer peripheral surface 6c. Flow prevention frame 8 is constituted by, for example, a single layer. Flow prevention frame 8 is constituted by, for example, a single material.

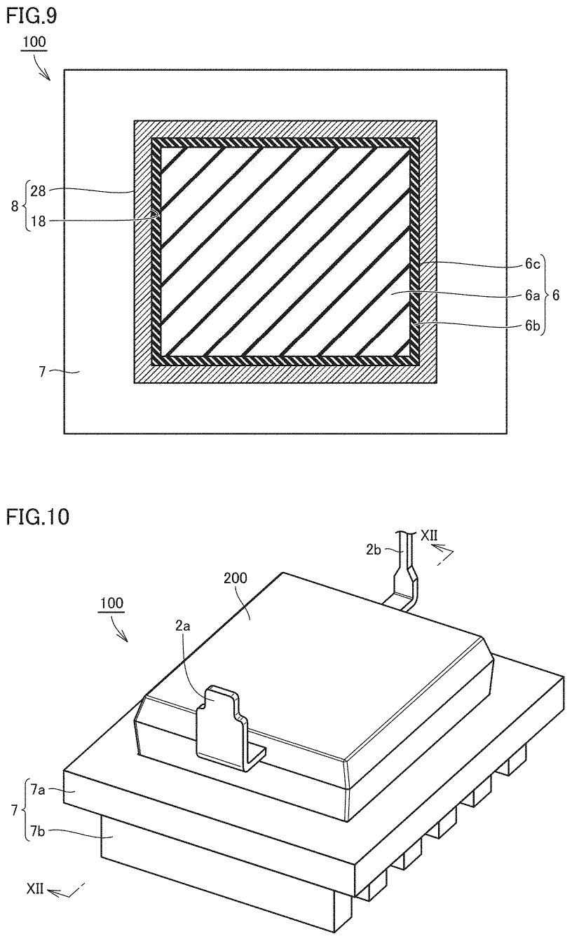

As illustrated in FIG. 3, outer peripheral portion 6b surrounds central portion 6a as viewed in the thickness direction of adhesive sheet 6. Outer peripheral portion 6b constitutes outer peripheral surface 6c. Outer peripheral surface 6c adjoins inner peripheral surface 18 of flow prevention frame 8. As illustrated in FIG. 3, inner peripheral surface 18 has, for example, a rectangular shape with rounded corners as viewed in the thickness direction of adhesive sheet 6. Inner peripheral surface 18 has a rounded corner portion 18a and a side portion 18b. Side portion 18b has a linear shape. Rounded corner portion 18a is continuous with side portion 18b. The radius of curvature of rounded corner portion 18a is greater than or equal to 1/30 of the length of the long side of the rectangle. The radius of curvature of rounded corner portion 18a may be greater than or equal to 1/20 or 1/10 of the length of the long side of the rectangle. As illustrated in FIG. 3, outer peripheral surface 6c may have, for example, a rectangular shape with rounded corners as viewed in the thickness direction of adhesive sheet 6. As illustrated in FIG. 9, outer peripheral surface 6c may have a rectangular shape as viewed in the thickness direction of adhesive sheet 6. Corner portion 18a of outer peripheral surface 6c may have a right angle instead of a rounded shape as viewed in the thickness direction of adhesive sheet 6.

FIG. 4 is a schematic cross-sectional view illustrating a manufacturing process of the power semiconductor device according to the first embodiment. As illustrated in FIG. 4, adhesive sheet 6 before thermal pressure bonding is placed inside inner peripheral surface 18 of flow prevention frame 8 with a gap 61 being provided between adhesive sheet 6 and inner peripheral surface 18. Next, power module unit 200 and support member 7 are firmly joined with adhesive sheet 6 therebetween. Specifically, power module unit 200 is bonded by being pressurized and heated at a pressure and a temperature by which the power module unit is not broken.

During thermal pressure bonding, the viscosity of the thermosetting resin contained in adhesive sheet 6 temporarily decreases. Adhesive sheet 6 flows with the application of pressure. Adhesive sheet 6 is deformed in each of a thickness direction (vertical direction in FIG. 2) and an in-plane direction (horizontal direction in FIG. 2). During deformation, a part of the ceramic, the thermosetting resin, and voids contained in adhesive sheet 6 flow. That is, gap 61 provided between adhesive sheet 6 and flow prevention frame 8 in the planar direction before the thermal pressure bonding is filled with outer peripheral portion 6b (flow portion) due to adhesive sheet 6 flowing by the thermal pressure bonding. After the thermal pressure bonding, the contact region between outer peripheral surface 6c of adhesive sheet 6 and inner peripheral surface 18 of flow prevention frame 8 may be a part of or entire circumference of outer peripheral surface 6c of adhesive sheet 6.

When adhesive sheet 6 is open in the in-plane direction (that is, when there is no flow prevention frame 8 of power semiconductor device 100 illustrated in FIG. 2), the pressure at the central portion of adhesive sheet 6 is the highest and the pressure at outer peripheral surface 6c is the lowest. Adhesive sheet 6 flows from the central portion of adhesive sheet 6 toward the outer peripheral side due to a pressure difference between the central portion and outer peripheral surface 6c. Adhesive sheet 6 deforms and flows under a pressure of, for example, about 10 MPa.

A part of the ceramic, the thermosetting resin, and the void flow from the central portion of adhesive sheet 6 toward the outer peripheral side under the pressing force at the time of bonding as a driving force and the fluid resistance in adhesive sheet 6 as a reaction force. The corner portion of outer peripheral surface 6c of adhesive sheet 6 is the farthest from the central portion of adhesive sheet 6. Therefore, the corner portion of outer peripheral surface 6c of adhesive sheet 6 has higher fluid resistance than the portions other than the corner portion of outer peripheral surface 6c. As a result, an amount of flow at the corner portion of outer peripheral surface 6c of adhesive sheet 6 is smaller than that at portions other than the corner portion of outer peripheral surface 6c. Therefore, in the corner portion of outer peripheral surface 6c of adhesive sheet 6, the internal pressure generated in adhesive sheet 6 decreases, and the void present in adhesive sheet 6 cannot be sufficiently crushed. As a result, a large number of voids remain in adhesive sheet 6, and bonding reliability, heat dissipation, and insulation reliability may be deteriorated.

According to power semiconductor device 100 according to the first embodiment, the internal pressure of outer peripheral surface 6c of adhesive sheet 6 is uniform. Specifically, a value obtained by dividing the maximum value of the internal pressure on outer peripheral surface 6c of adhesive sheet 6 by the minimum value of the internal pressure on outer peripheral surface 6c of adhesive sheet 6 is less than or equal to 10. The value obtained by dividing the maximum value of the internal pressure on outer peripheral surface 6c of adhesive sheet 6 by the minimum value of the internal pressure on outer peripheral surface 6c of adhesive sheet 6 may be less than or equal to 5 or less than or equal to 2. When the outer shape of adhesive sheet 6 is rectangular, it is likely that the internal pressure at the corner portion of the rectangle is minimized, and the internal pressure at the center of the long side of the rectangle is maximized. The internal pressure at the center of the long side of the rectangle may be less than or equal to 10 times the internal pressure at the corner portion of the rectangle.

Next, a method for calculating the internal pressure on the outer peripheral surface of the adhesive sheet will be described. The internal pressure on the outer peripheral surface of the adhesive sheet is obtained by calculation using structural parameters of the flow prevention frame, the adhesive sheet, and the like. The method for calculating the internal pressure on the outer peripheral surface of the adhesive sheet includes, for example, a method for applying the Ergun equation.

The material of flow prevention frame 8 has strength enough to restrict adhesive sheet 6 that deforms and flows under high pressure of, for example, 10 MPa. Before thermal pressure bonding, the height of flow prevention frame 8 is desirably larger than the height of adhesive sheet 6. Flow prevention frame 8 is deformed by the thermal pressure bonding. After the thermal pressure bonding, the thickness of flow prevention frame 8 is desirably equal to or larger than the thickness of adhesive sheet 6.

According to power semiconductor device 100 according to the first embodiment, the internal pressure of outer peripheral surface 6c of adhesive sheet 6 is uniform. Therefore, the number and size of voids remaining in adhesive sheet 6 are reduced. The size (diameter) of the void present in adhesive sheet 6 may be less than or equal to 20 for example. With this configuration, the adhesiveness, heat dissipation, and insulation of adhesive sheet 6 can be improved. As a result, the reliability of power semiconductor device 100 can be improved. Therefore, it is possible to suppress an increase in the mounting area and an increase in cost due to the formation of an extra design margin.

### Second Embodiment

Next, a configuration of power semiconductor device 100 according to the second embodiment will be described. The same components as those of power semiconductor device 100 according to the first embodiment are denoted by the same reference numerals as those of power semiconductor device 100 according to the first embodiment, and the description thereof will not be repeated. A configuration different from power semiconductor device 100 according to the first embodiment will be mainly described below.

FIG. 5 is a schematic cross-sectional view illustrating a configuration of power semiconductor device 100 according to the second embodiment. The cross section in FIG. 5 corresponds to the cross section taken along line III-III in FIG. 2. As illustrated in FIG. 5, inner peripheral surface 18 of flow prevention frame 8 is circular as viewed in the thickness direction of adhesive sheet 6. Similarly, outer peripheral surface 6c of adhesive sheet 6 is circular. Flow prevention frame 8 has a ring shape. When viewed in the thickness direction of adhesive sheet 6, the distance between the center of adhesive sheet 6 and inner peripheral surface 18 of flow prevention frame 8 (or outer peripheral surface 6c of adhesive sheet 6) is the same at any point on inner peripheral surface 18. As a result, the fluid resistance during thermal pressure bonding can be made constant. As a result, an amount of flow of adhesive sheet 6 can be made uniform in all directions in the plane as viewed from the center of adhesive sheet 6. Thus, the internal pressure of outer peripheral surface 6c of adhesive sheet 6 can be made uniform.

### Third Embodiment

Next, a configuration of power semiconductor device 100 according to the third embodiment will be described. The same components as those of power semiconductor device 100 according to the first embodiment are denoted by the same reference numerals as those of power semiconductor device 100 according to the first embodiment, and the description thereof will not be repeated. A configuration different from power semiconductor device 100 according to the first embodiment will be mainly described below.

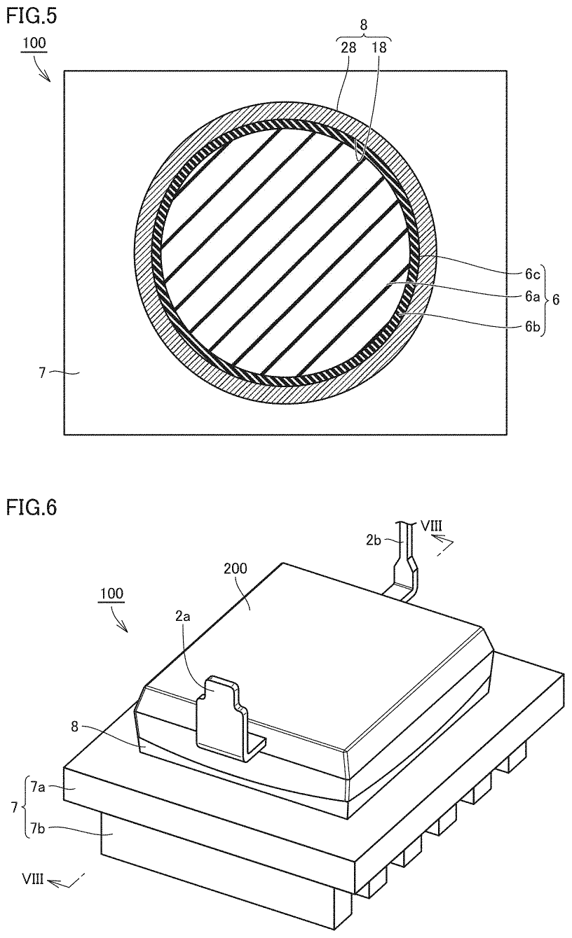

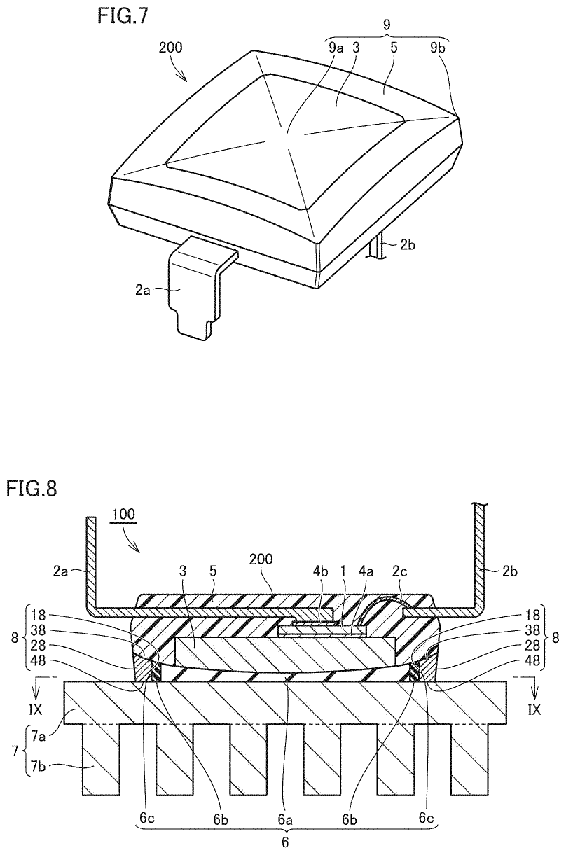

FIG. 6 is a schematic perspective view illustrating a configuration of power semiconductor device 100 according to the third embodiment. FIG. 7 is a schematic perspective view illustrating a configuration of power module unit 200 of power semiconductor device 100 according to the third embodiment.

As illustrated in FIG. 7, power module unit 200 has a joint surface 9. Joint surface 9 is a surface in contact with adhesive sheet 6. Joint surface 9 includes heat spreader 3 and mold resin portion 5. Joint surface 9 has a curved shape. Power module unit 200 is the thinnest at the corner portion (first corner portion 9b) of joint surface 9 and the thickest at the center (first center 9a) of joint surface 9. Joint surface 9 may be a convex curved surface radially and continuously extending from the center (first center 9a).

FIG. 8 is a cross-sectional view taken along line VIII-VIII in FIG. 6. FIG. 8 illustrates the cross section parallel to the thickness direction of adhesive sheet 6. As illustrated in FIG. 8, in the cross section, the thickness of adhesive sheet 6 may increase from central portion 6a toward outer peripheral surface 6c. In the cross section, the thickness of outer wall surface 28 of flow prevention frame 8 may be larger than the thickness of inner peripheral surface 18 of flow prevention frame 8. The thickness of outer peripheral surface 6c of adhesive sheet 6 may be larger than the maximum value of the thickness of central portion 6a of adhesive sheet 6.

Flow prevention frame 8 has a first face 38 and a second face 48. Second face 48 is on the opposite side of first face 38. First face 38 is in contact with mold resin portion 5. Second face 48 is in contact with support member 7. The distance between first face 38 and second face 48 may increase from inner peripheral surface 18 toward outer wall surface 28. First face 38 may be curved. Second face 48 may be flat.

FIG. 9 is a cross-sectional view taken along line IX-IX in FIG. 8. As illustrated in FIG. 9, inner peripheral surface 18 of flow prevention frame 8 may be square or rectangular as viewed in the thickness direction of adhesive sheet 6. Similarly, outer shape of adhesive sheet 6 may be square or rectangular. Outer wall surface 28 of flow prevention frame 8 may be square or rectangular. The thickness of adhesive sheet 6 at the corner portion of outer peripheral surface 6c of adhesive sheet 6 may be larger than the thickness of adhesive sheet 6 at the center of one side of outer peripheral surface 6c of adhesive sheet 6.

In power semiconductor device 100 according to the third embodiment, the gap between adhesive sheet 6 and power module unit 200 in the thickness direction is the widest at the corner portion of outer peripheral surface 6c farthest from the center of adhesive sheet 6 before the thermal pressure bonding. In general, the larger the cross-sectional area of a flow path, the easier the fluid flows. Therefore, by increasing the gap between adhesive sheet 6 and power module unit 200 in the thickness direction, an effect of increasing an amount of flow of adhesive sheet 6 can be expected.

In power semiconductor device 100 according to the third embodiment, power module unit 200 is the thinnest at the corner portion (first corner portion 9b) of joint surface 9 and the thickest at the center (first center 9a) of joint surface 9. Therefore, the difference in amount of flow of adhesive sheet 6 on the outer periphery of adhesive sheet 6 can be reduced. Thus, it can be expected to uniformize the internal pressure of adhesive sheet 6. As a result, the bonding reliability, heat dissipation, and insulation reliability of power semiconductor device 100 can be improved. Therefore, it is possible to suppress an increase in the mounting area and an increase in cost due to the formation of an extra design margin.

### Fourth Embodiment

Next, a configuration of power semiconductor device 100 according to the fourth embodiment will be described. The same components as those of power semiconductor device 100 according to the first embodiment are denoted by the same reference numerals as those of power semiconductor device 100 according to the first embodiment, and the description thereof will not be repeated. A configuration different from power semiconductor device 100 according to the first embodiment will be mainly described below.

FIG. 10 is a schematic perspective view illustrating a configuration of power semiconductor device 100 according to the fourth embodiment. FIG. 11 is a schematic perspective view illustrating a configuration of a support member of power semiconductor device 100 according to the fourth embodiment.

As illustrated in FIG. 11, support member 7 has a top face 15. Top face 15 is a surface facing adhesive sheet 6. Top face 15 is constituted by body portion 7a. Top face 15 has an upper face 16, a lateral face 11a, and a bottom face 11b. Upper face 16 is continuous with lateral face 11a. Lateral face 11a is continuous with bottom face 11b. Upper face 16 is separated from bottom face 11b. Top face 15 is provided with a groove 11. Groove 11 is defined by lateral face 11a and bottom face 11b. Groove 11 is the deepest at the corner portion (second corner portion 15b) of bottom face 11b and the shallowest at the center (second center 15a) of the bottom face. Bottom face 11b may be a convex curved surface radially and continuously extending from the center (second center 15a).

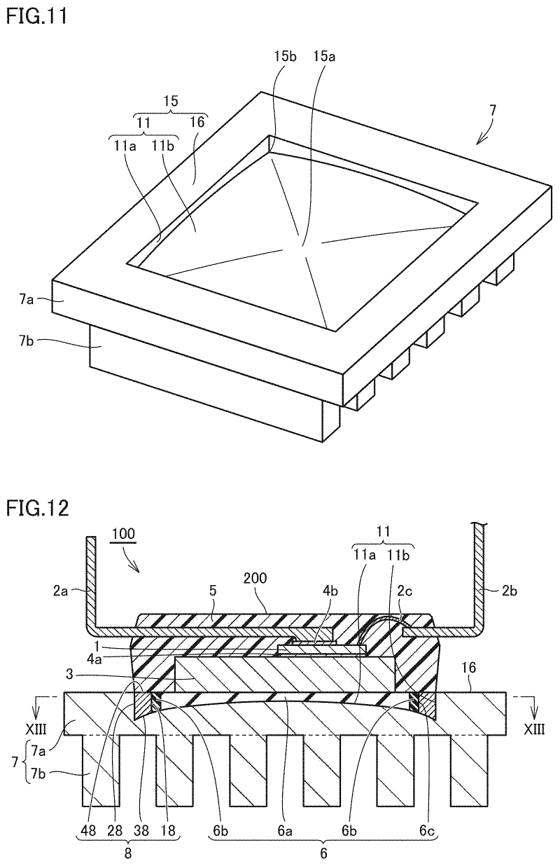

FIG. 12 is a cross-sectional view taken along line XII-XII in FIG. 10. FIG. 12 illustrates the cross section parallel to the thickness direction of adhesive sheet 6. As illustrated in FIG. 12, adhesive sheet 6 and flow prevention frame 8 may be provided inside groove 11. Adhesive sheet 6 and flow prevention frame 8 may be in contact with bottom face 11b of groove 11. Flow prevention frame 8 may be in contact with lateral face 11a of groove 11. As illustrated in FIG. 12, in the cross section, the thickness of adhesive sheet 6 may increase from central portion 6a toward outer peripheral surface 6c. In the cross section, the thickness of outer wall surface 28 of flow prevention frame 8 may be larger than the thickness of inner peripheral surface 18 of flow prevention frame 8. The thickness of outer peripheral surface 6c of adhesive sheet 6 may be larger than the maximum value of the thickness of central portion 6a.

Flow prevention frame 8 has first face 38 and second face 48. Second face 48 is on the opposite side of first face 38. First face 38 is in contact with mold resin portion 5. Second face 48 is in contact with support member 7. The distance between first face 38 and second face 48 may increase from inner peripheral surface 18 toward outer wall surface 28. First face 38 may be flat. Second face 48 may be curved.

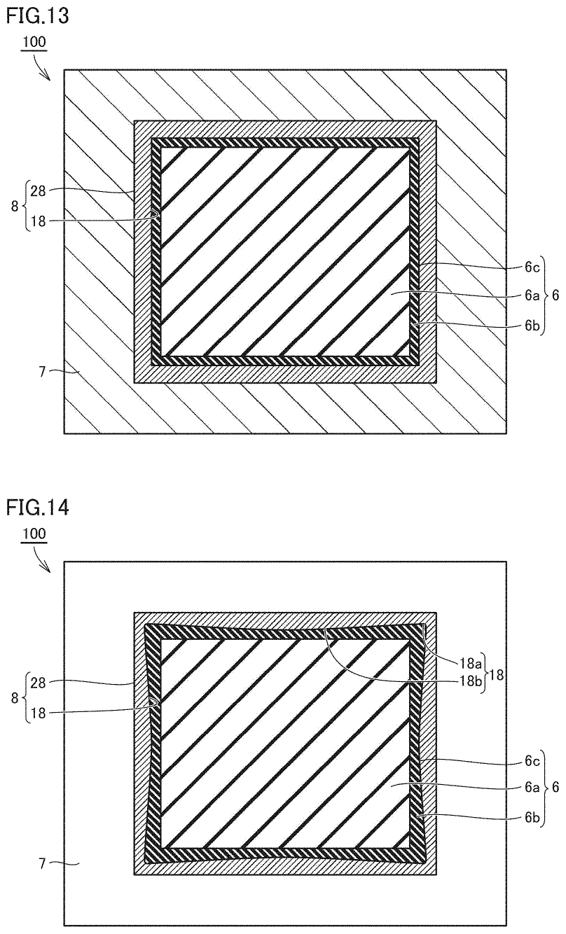

FIG. 13 is a cross-sectional view taken along line XIII-XIII in FIG. 12. As illustrated in FIG. 13, inner peripheral surface 18 of flow prevention frame 8 may be square or rectangular as viewed in the thickness direction of adhesive sheet 6. Similarly, outer peripheral surface 6c of adhesive sheet 6 may be square or rectangular. Outer wall surface 28 of flow prevention frame 8 may be square or rectangular. The thickness of adhesive sheet 6 at the corner portion of outer peripheral surface 6c of adhesive sheet 6 may be larger than the thickness of adhesive sheet 6 at the center of one side of outer peripheral surface 6c of adhesive sheet 6.

In power semiconductor device 100 according to the fourth embodiment, the gap between adhesive sheet 6 and power module unit 200 in the thickness direction is the widest at the corner portion of outer peripheral surface 6c farthest from the center of adhesive sheet 6 before the thermal pressure bonding. In general, the larger the cross-sectional area of a flow path, the easier the fluid flows. Therefore, by increasing the gap between adhesive sheet 6 and power module unit 200 in the thickness direction, an effect of increasing an amount of flow of adhesive sheet 6 can be expected.

In power semiconductor device 100 according to the fourth embodiment, the depth of groove 11 is the largest at the corner portion (second corner portion 15b) of bottom face 11b and the smallest at the center (second center 15a) of bottom face 11b. Therefore, the difference in amount of flow of adhesive sheet 6 on the outer periphery of adhesive sheet 6 can be reduced. Thus, it can be expected to uniformize the internal pressure of adhesive sheet 6. As a result, the bonding reliability, heat dissipation, and insulation reliability of power semiconductor device 100 can be improved. Therefore, it is possible to suppress an increase in the mounting area and an increase in cost due to the formation of an extra design margin.

### Fifth Embodiment

Next, a configuration of power semiconductor device 100 according to the fifth embodiment will be described. The same components as those of power semiconductor device 100 according to the first embodiment are denoted by the same reference numerals as those of power semiconductor device 100 according to the first embodiment, and the description thereof will not be repeated. A configuration different from power semiconductor device 100 according to the first embodiment will be mainly described below.

FIG. 14 is a schematic cross-sectional view illustrating a configuration of power semiconductor device 100 according to the fifth embodiment. The cross section in FIG. 14 corresponds to the cross section taken along line III-III in FIG. 2. As illustrated in FIG. 14, inner peripheral surface 18 has corner portion 18a and side portion 18b as viewed in the thickness direction of adhesive sheet 6. Side portion 18b is continuous with corner portion 18a. Side portion 18b is curved so as to protrude inward. As illustrated in FIG. 14, the width of flow prevention frame 8 decreases from the center of side portion 18b toward corner portion 18a as viewed in the thickness direction of adhesive sheet 6. Outer wall surface 28 of flow prevention frame 8 may be rectangular or square.

Flow prevention frame 8 is, for example, a solid material. Before thermal pressure bonding, the thickness of flow prevention frame 8 is greater than or equal to the thickness of adhesive sheet 6. Flow prevention frame 8 is deformed during thermal pressure bonding. After the thermal pressure bonding, the thickness of flow prevention frame 8 is greater than or equal to the thickness of adhesive sheet 6. The material having the above characteristics is, for example, soft metal such as tin or a silicone-based rubber material.

In power semiconductor device 100 according to the fifth embodiment, the clearance in the in-plane direction between inner peripheral surface 18 of flow prevention frame 8 and outer peripheral surface 6c of adhesive sheet 6 continuously changes so as to be widest at the corner portion. When coming into contact with flow prevention frame 8, outer peripheral surface 6c of adhesive sheet 6 that flows at the time of thermal pressure bonding cannot flow any more. Therefore, adhesive sheet 6 easily flows to the side where the clearance is wide, that is, the corner side of adhesive sheet 6. Thus, the internal pressure of outer peripheral surface 6c of adhesive sheet 6 can be made uniform.

### Sixth Embodiment

Next, a configuration of power semiconductor device 100 according to the sixth embodiment will be described. The same components as those of power semiconductor device 100 according to the first embodiment are denoted by the same reference numerals as those of power semiconductor device 100 according to the first embodiment, and the description thereof will not be repeated. A configuration different from power semiconductor device 100 according to the first embodiment will be mainly described below.

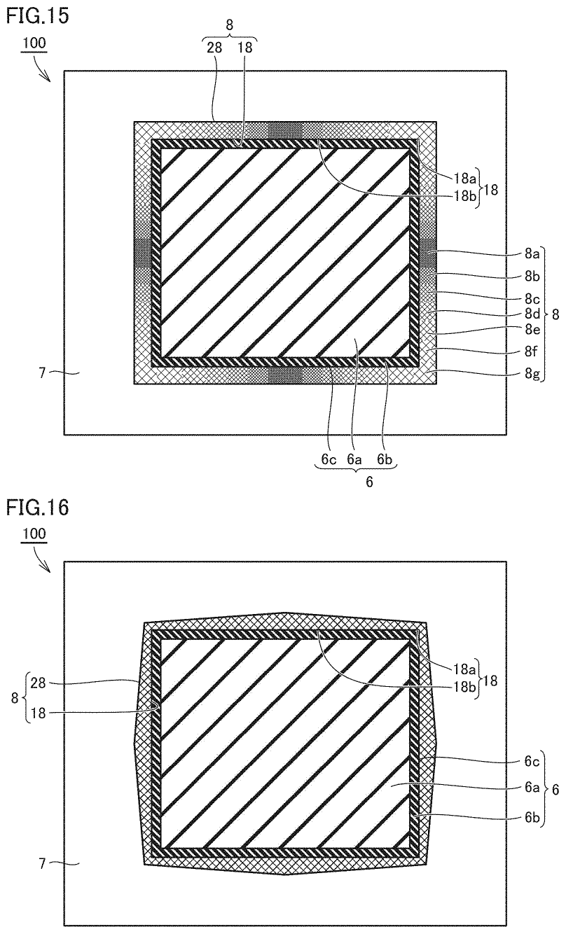

FIG. 15 is a schematic cross-sectional view illustrating a configuration of power semiconductor device 100 according to the sixth embodiment. The cross section in FIG. 15 corresponds to the cross section taken along line III-III in FIG. 2. In power semiconductor device 100 according to the sixth embodiment, flow prevention frame 8 is formed of a porous body. Unlike the first to fifth embodiments, adhesive sheet 6 flowing during thermal pressure bonding enters the inside of flow prevention frame 8. When adhesive sheet 6 passes through the inside of flow prevention frame 8, fluid resistance is generated against adhesive sheet 6. Therefore, the flow of adhesive sheet 6 can be restricted. Thus, the internal pressure of adhesive sheet 6 can be made uniform. As the material of flow prevention frame 8, a material by which adhesive sheet 6 deforms in the similar manner as in the fifth embodiment is selected. The material of flow prevention frame 8 is, for example, a porous body such as cellulose fiber, glass fiber, foamed resin, or porous ceramics.

As illustrated in FIG. 15, inner peripheral surface 18 has corner portion 18a and side portion 18b as viewed in the thickness direction of adhesive sheet 6. Side portion 18b is continuous with corner portion 18a. Side portion 18b has a linear shape. The pore diameter of the porous body increases from the center of side portion 18b toward corner portion 18a. Specifically, the pore diameter of flow prevention frame 8 at corner portion 18a is the largest, and the pore diameter of flow prevention frame 8 at the center of side portion 18b is the smallest.

As illustrated in FIG. 15, flow prevention frame 8 may include a first region 8a, a second region 8b, a third region 8c, a fourth region 8d, a fifth region 8e, a sixth region 8f, and a seventh region 8g. First region 8a constitutes the center of the side portion. Fifth region 8e constitutes the corner portion. Second region 8b is located on each side of first region 8a. Third region 8c is located between second region 8b and fourth region 8d. Fourth region 8d is located between third region 8c and fifth region 8e. Fifth region 8e is located between fourth region 8d and sixth region 8f. Sixth region 8f is located between fifth region 8e and seventh region 8g. Seventh region 8g is a corner portion of flow prevention frame 8.

The pore diameter in second region 8b is larger than the pore diameter in first region 8a. The pore diameter in third region 8c is larger than the pore diameter in second region 8b. The pore diameter in fourth region 8d is larger than the pore diameter in third region 8c. The pore diameter in fifth region 8e is larger than the pore diameter in fourth region 8d. The pore diameter in sixth region 8f is larger than the pore diameter in fifth region 8e. The pore diameter in seventh region 8g is larger than the pore diameter in sixth region 8f.

As another mode, in a case where the pore diameters are the same, the density of the pores of flow prevention frame 8 at the corner portion may be the highest, and the density of the pores of flow prevention frame 8 at the center of the side portion may be the lowest. Specifically, the density of the pores in second region 8b may be higher than the density of the pores in first region 8a. The density of the pores in third region 8c may be higher than the density of the pores in second region 8b. The density of the pores in fourth region 8d may be higher than the density of the pores in third region 8c. The density of the pores in fifth region 8e may be higher than the density of the pores in fourth region 8d. The density of the pores in sixth region 8f may be higher than the density of the pores in fifth region 8e. The density of the pores in seventh region 8g may be higher than the density of the pores in sixth region 8f.

In power semiconductor device 100 according to the sixth embodiment, when adhesive sheet 6 passes through the inside of flow prevention frame 8, the fluid resistance is the largest at the center of the side portion, and the fluid resistance is the smallest at the corner portion. Therefore, adhesive sheet 6 easily flows to the corner side of adhesive sheet 6. Thus, the internal pressure of outer peripheral surface 6c of adhesive sheet 6 can be made uniform.

### Seventh Embodiment

Next, a configuration of power semiconductor device 100 according to the seventh embodiment will be described. The same components as those of power semiconductor device 100 according to the first embodiment are denoted by the same reference numerals as those of power semiconductor device 100 according to the first embodiment, and the description thereof will not be repeated. A configuration different from power semiconductor device 100 according to the first embodiment will be mainly described below.

FIG. 16 is a schematic cross-sectional view illustrating a configuration of power semiconductor device 100 according to the seventh embodiment. The cross section in FIG. 16 corresponds to the cross section taken along line III-III in FIG. 2. In power semiconductor device 100 according to the seventh embodiment, flow prevention frame 8 is formed of a porous body. As illustrated in FIG. 16, inner peripheral surface 18 has corner portion 18a and side portion 18b as viewed in the thickness direction of adhesive sheet 6. Side portion 18b is continuous with corner portion 18a. Side portion 18b has a linear shape. As illustrated in FIG. 16, the width of flow prevention frame 8 decreases from the center of side portion 18b toward corner portion 18a. From another point of view, the width of flow prevention frame 8 at the center of side portion 18b is the largest, and the width of flow prevention frame 8 at corner portion 18a is the smallest.

In power semiconductor device 100 according to the seventh embodiment, when adhesive sheet 6 passes through the inside of flow prevention frame 8, the fluid resistance is the largest at the center of the side portion, and the fluid resistance is the smallest at the corner portion. Therefore, adhesive sheet 6 easily flows to the corner side of adhesive sheet 6. Thus, the internal pressure of outer peripheral surface 6c of adhesive sheet 6 can be made uniform.

### Eighth Embodiment

Next, a configuration of power semiconductor device 100 according to the eighth embodiment will be described. The same components as those of power semiconductor device 100 according to the first embodiment are denoted by the same reference numerals as those of power semiconductor device 100 according to the first embodiment, and the description thereof will not be repeated. A configuration different from power semiconductor device 100 according to the first embodiment will be mainly described below.

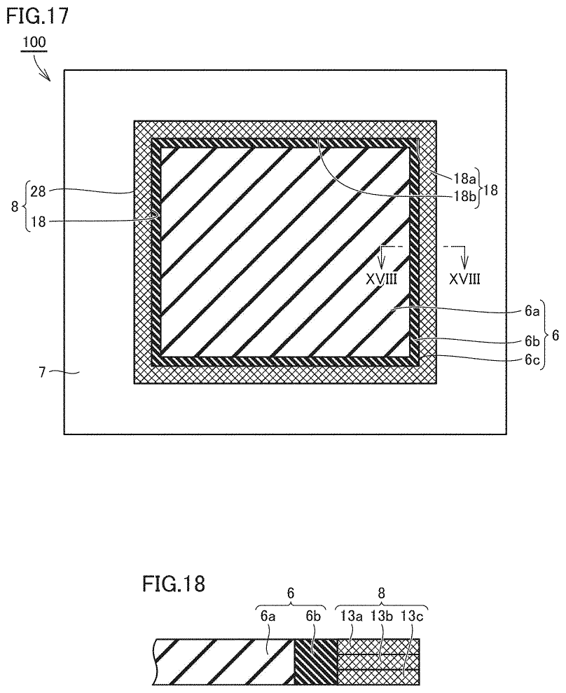

FIG. 17 is a schematic cross-sectional view illustrating a configuration of power semiconductor device 100 according to the eighth embodiment. The cross section in FIG. 17 corresponds to the cross section taken along line III-III in FIG. 2. FIG. 18 is a cross-sectional view taken along line XVIII-XVIII in FIG. 17. As illustrated in FIG. 18, in power semiconductor device 100 according to the eighth embodiment, flow prevention frame 8 may include two or more layers of different materials. As illustrated in FIG. 18, flow prevention frame 8 has a plurality of layers laminated in the thickness direction. Specifically, flow prevention frame 8 includes, for example, a first layer 13a, a second layer 13b, and a third layer 13c. Second layer 13b is on third layer 13c. First layer 13a is on second layer 13b. Second layer 13b is located between first layer 13a and third layer 13c. The material of first layer 13a is different from the material of second layer 13b. The material of third layer 13c is different from the material of second layer 13b. For example, the material of first layer 13a may be a porous body, and the material of second layer 13b may be a solid material. The solid material is, for example, soft metal such as tin or a silicone-based rubber material.

According to power semiconductor device 100 according to the eighth embodiment, flow prevention frame 8 having a desired thickness can be formed by laminating a plurality of materials each of which is difficult to be increased in thickness. This makes it possible to enlarge the range of choice for the material of flow prevention frame 8, which is advantageous in terms of simple choice and material cost.

Next, a configuration of power semiconductor device 100 according to a first modification of the eighth embodiment will be described. Power semiconductor device 100 according to the first modification of the eighth embodiment uses flow prevention frame 8 having the shape illustrated in FIG. 14. Specifically, as illustrated in FIG. 14, inner peripheral surface 18 of flow prevention frame 8 has corner portion 18a and side portion 18b as viewed in the thickness direction of adhesive sheet 6. Side portion 18b is continuous with corner portion 18a. Side portion 18b is curved so as to protrude inward. The width of flow prevention frame 8 decreases from the center of side portion 18b toward corner portion 18a.

Next, a configuration of power semiconductor device 100 according to a second modification of the eighth embodiment will be described. Power semiconductor device 100 according to the second modification of the eighth embodiment uses flow prevention frame 8 having the shape illustrated in FIG. 15. Specifically, flow prevention frame 8 is made of a porous body. As illustrated in FIG. 15, inner peripheral surface 18 has corner portion 18a and side portion 18b as viewed in the thickness direction of adhesive sheet 6. Side portion 18b is continuous with corner portion 18a. Side portion 18b has a linear shape. The pore diameter of the porous body increases from the center of side portion 18b toward corner portion 18a. The density of the pores of the porous body may increase from the center of side portion 18b toward corner portion 18a.

Next, a configuration of power semiconductor device 100 according to a third modification of the eighth embodiment will be described. Power semiconductor device 100 according to the third modification of the eighth embodiment uses flow prevention frame 8 having the shape illustrated in FIG. 16. Specifically, flow prevention frame 8 is made of a porous body. As illustrated in FIG. 16, inner peripheral surface 18 has corner portion 18a and side portion 18b as viewed in the thickness direction of adhesive sheet 6. Side portion 18b is continuous with corner portion 18a. Side portion 18b has a linear shape. The width of flow prevention frame 8 decreases from the center of side portion 18b toward corner portion 18a.

### Ninth Embodiment

Next, a configuration of power semiconductor device 100 according to the ninth embodiment will be described. The same components as those of power semiconductor device 100 according to the first embodiment are denoted by the same reference numerals as those of power semiconductor device 100 according to the first embodiment, and the description thereof will not be repeated. A configuration different from power semiconductor device 100 according to the first embodiment will be mainly described below.

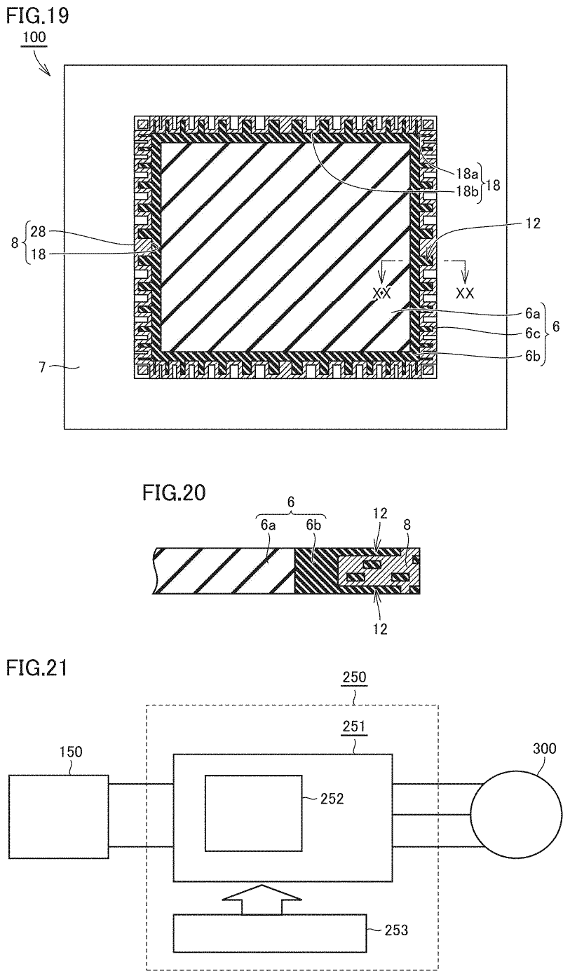

FIG. 19 is a schematic cross-sectional view illustrating a configuration of power semiconductor device 100 according to the ninth embodiment. The cross section in FIG. 19 corresponds to the cross section taken along line III-III in FIG. 2. FIG. 20 is a cross-sectional view taken along line XX-XX in FIG. 19. As illustrated in FIG. 19, inner peripheral surface 18 has corner portion 18a and side portion 18b as viewed in the thickness direction of adhesive sheet 6. Side portion 18b is continuous with corner portion 18a. As illustrated in FIGS. 19 and 20, power semiconductor device 100 according to the ninth embodiment has a plurality of recesses 12 provided in inner peripheral surface 18. The density of the plurality of recesses 12 decreases from the center of the side portion toward the corner portion. The material of flow prevention frame 8 is, for example, a solid material. The plurality of recesses 12 may be distributed in the thickness direction of flow prevention frame 8 as illustrated in FIG. 20, or may be distributed in the width direction of flow prevention frame 8. Adhesive sheet 6 enters at least a part of the plurality of recesses 12. The plurality of recesses 12 may be exposed on outer wall surface 28 of flow prevention frame 8.

In power semiconductor device 100 according to the ninth embodiment, when adhesive sheet 6 passes through the inside of flow prevention frame 8, the fluid resistance is the largest at the center of the side portion, and the fluid resistance is the smallest at the corner portion. Therefore, adhesive sheet 6 easily flows to the corner side of adhesive sheet 6. Thus, the internal pressure of outer peripheral surface 6c of adhesive sheet 6 can be made uniform.

### Tenth Embodiment

In the present embodiment, power semiconductor device 100 according to any one of the first to ninth embodiments is applied to a power conversion device. The tenth embodiment will describe a case where the present disclosure is applied to a three-phase inverter, although the present disclosure is not limited to a specific power conversion device.

FIG. 21 is a block diagram illustrating a configuration of a power conversion system to which the power conversion device according to the tenth embodiment is applied.

The power conversion system illustrated in FIG. 21 includes a power supply 150, a power conversion device 250, and a load 300. Power supply 150 is a DC power supply, and supplies DC power to power conversion device 250. Power supply 150 can be of any type. For example, power supply 150 can be a DC system, a solar cell, and a storage battery, or may be constituted by a rectifier circuit or an AC/DC converter connected to an AC system. Alternatively, power supply 150 may be constituted by a DC/DC converter that converts DC power output from the DC system into predetermined power.

Power conversion device 250 is a three-phase inverter connected between power supply 150 and load 300, converts DC power supplied from power supply 150 into AC power, and supplies the AC power to load 300. As illustrated in FIG. 21, power conversion device 250 includes a main conversion circuit 251 that converts DC power into AC power and outputs the AC power, and a control circuit 253 that outputs a control signal for controlling main conversion circuit 251 to main conversion circuit 251.

Load 300 is a three-phase electric motor driven by the AC power supplied from power conversion device 250. Load 300 is not limited to a specific application, and is an electric motor mounted on various electric devices such as an electric motor for a hybrid vehicle, an electric vehicle, a railway vehicle, an elevator, or an air conditioner.

The detail of power conversion device 250 will be described below. Main conversion circuit 251 includes a switching element and a freewheeling diode (not illustrated), converts DC power supplied from power supply 150 into AC power by switching of the switching element, and supplies the AC power to load 300. Although there are various specific circuit structures of main conversion circuit 251, main conversion circuit 251 according to the present embodiment can be a two-level three-phase full bridge circuit including six switching elements and six freewheeling diodes antiparallel to the respective switching elements. Each switching element and each freewheeling diode of main conversion circuit 251 are constituted by a semiconductor module 252 corresponding to any one of the above-described first to ninth embodiments. The six switching elements are connected in series for every two switching elements to constitute upper and lower arms, and each of the upper and lower arms constitutes each phase (U-phase, V-phase, W-phase) of the full bridge circuit. The output terminals of the upper and lower arms, that is, the three output terminals of main conversion circuit 251, are connected to load 300.

Further, main conversion circuit 251 includes a drive circuit (not illustrated) that drives each switching element. The drive circuit may be built in semiconductor module 252, or may be provided separately from semiconductor module 252. The drive circuit generates a drive signal for driving the switching elements of main conversion circuit 251, and supplies the drive signal to control electrodes of the switching elements of main conversion circuit 251. Specifically, the drive circuit outputs, to the control electrode of each switching element, a drive signal for turning on the switching element and a drive signal for turning off the switching element in accordance with a control signal from control circuit 253 to be described later. When the switching element is maintained in the ON state, the drive signal is a voltage signal (ON signal) equal to or higher than a threshold voltage of the switching element, and when the switching element is maintained in the OFF state, the drive signal is a voltage signal (OFF signal) equal to or lower than the threshold voltage of the switching element.

Control circuit 253 controls the switching elements of main conversion circuit 251 so that desired power is supplied to load 300. Specifically, control circuit 253 calculates, on the basis of power to be supplied to load 300, a time (ON time) during which each switching element of main conversion circuit 251 is to be turned on. For example, control circuit 253 can control main conversion circuit 251 by PWM control that modulates the ON time of the switching element according to the voltage to be output. Then, control circuit 253 outputs a control command (control signal) to the drive circuit included in main conversion circuit 251 such that, at each time point, the ON signal is output to the switching element to be turned on and the OFF signal is output to the switching element to be turned off. The drive circuit outputs the ON signal or the OFF signal as a drive signal to the control electrode of each switching element in accordance with the control signal.

The power conversion device according to the present embodiment uses power semiconductor device 100 according to any one of the first to ninth embodiments as the switching element and the freewheeling diode of main conversion circuit 251, whereby the reliability of the power conversion device can be improved.

The present embodiment has described the example in which the present invention is applied to a two-level three-phase inverter. However, the present disclosure is not limited thereto, and can be applied to various power conversion devices. In the present embodiment, the two-level power conversion device has been described. However, a three-level or multi-level power conversion device may be used, or the present disclosure may be applied to a single-phase inverter in a case where power is supplied to a single-phase load. In addition, in a case where power is supplied to a DC load or the like, the present disclosure can also be applied to a DC/DC converter or an AC/DC converter.

In addition, the power conversion device to which the present disclosure is applied is not limited to the one described above used for an electric motor serving as a load, and can be used as, for example, a power supply device of an electric discharge machine, a laser beam machine, an induction heating cooker, or a non-contact power feeding system, and as a power conditioner of a solar power generation system, a power storage system, or the like.

It should be understood that the embodiments disclosed herein are illustrative in all respects and not restrictive. At least two of the embodiments disclosed herein may be combined as long as there is no contradiction. The scope of the present application is defined not by the above description but by the claims, and is intended to include meanings equivalent to the claims and all modifications within the scope.

### REFERENCE SIGNS LIST

1: power semiconductor element, 2a: first metal wiring member, 2b: second metal wiring member, 2c: third metal wiring member, 3: heat spreader, 4a: first metal bonding member, 4b: second metal bonding member, 5: mold resin portion, 6: adhesive sheet, 6a: central portion, 6b: outer peripheral portion, 6c: outer peripheral surface, 7: support member, 7a: body portion, 7b: fin, 8: flow prevention frame, 8a: first region, 8b: second region, 8c: third region, 8d: fourth region, 8e: fifth region, 8f: sixth region, 8g: seventh region, 9: joint surface, 9a: first center, 9b: first corner portion, 11: groove, 11a: lateral face, 11b: bottom face, 12: recess, 13a: first layer, 13b: second layer, 13c: third layer, 15: top face, 15a: second center, 15b: second corner portion, 16: upper face, 18: inner peripheral surface, 18a: corner portion, 18b: side portion, 28: outer wall surface, 38: first face, 48: second face, 61: gap, 100: power semiconductor device, 150: power supply, 200: power module unit, 250: power conversion device, 251: main conversion circuit, 252: semiconductor module, 253: control circuit, 300: load

1. A power semiconductor device comprising:
a power module unit;
an adhesive sheet bonded to the power module unit;
a support member connected to the power module unit with the adhesive sheet interposed between the power module unit and the support member; and
a flow prevention frame sandwiched between the power module unit and the support member and placed around the adhesive sheet, wherein
the flow prevention frame is made of a porous body,
the adhesive sheet has an outer peripheral surface adjoining an inner peripheral surface of the flow prevention frame, and
a value obtained by dividing a maximum value of an internal pressure on the outer peripheral surface by a minimum value of the internal pressure is more than or equal to 1 and less than or equal to 10.

2. The power semiconductor device according to claim 1, wherein
the inner peripheral surface has a rectangular shape with a corner portion that is rounded as viewed in a thickness direction of the adhesive sheet.

3. The power semiconductor device according to claim 1, wherein the inner peripheral surface is circular as viewed in a thickness direction of the adhesive sheet.

4. The power semiconductor device according to claim 1, wherein
the adhesive sheet includes a central portion surrounded by the outer peripheral surface, and
the adhesive sheet has a thickness that increases from the central portion toward the outer peripheral surface.

5. The power semiconductor device according to claim 1, wherein the flow prevention frame includes a single layer.

6. The power semiconductor device according to claim 5, wherein
the inner peripheral surface has a corner portion and a side portion continuous with the corner portion as viewed in a thickness direction of the adhesive sheet, the side portion being bent so as to protrude inward, and
the flow prevention frame has a width that decreases from a center of the side portion toward the corner portion.

7. The power semiconductor device according to claim 5, wherein
the inner peripheral surface has a corner portion and a side portion continuous with the corner portion as viewed in a thickness direction of the adhesive sheet, the side portion being linear, and
a pore diameter of the porous body increases from a center of the side portion toward the corner portion.

8. The power semiconductor device according to claim 5, wherein
the inner peripheral surface has a corner portion and a side portion continuous with the corner portion as viewed in a thickness direction of the adhesive sheet, the side portion being linear, and
the flow prevention frame has a width that decreases from a center of the side portion toward the corner portion.

9. The power semiconductor device according to claim 1, wherein the flow prevention frame includes two or more layers made of different materials.

10. The power semiconductor device according to claim 9, wherein
the inner peripheral surface has a corner portion and a side portion continuous with the corner portion as viewed in a thickness direction of the adhesive sheet, the side portion being bent so as to protrude inward, and
the flow prevention frame has a width that decreases from a center of the side portion toward the corner portion.

11. The power semiconductor device according to claim 9, wherein
the inner peripheral surface has a corner portion and a side portion continuous with the corner portion as viewed in a thickness direction of the adhesive sheet, the side portion being linear, and
a pore diameter of the porous body increases from a center of the side portion toward the corner portion.

12. The power semiconductor device according to claim 9, wherein
the inner peripheral surface has a corner portion and a side portion continuous with the corner portion as viewed in a thickness direction of the adhesive sheet, the side portion being linear, and
the flow prevention frame has a width that decreases from a center of the side portion toward the corner portion.

13. The power semiconductor device according to claim 9, wherein
the inner peripheral surface has a corner portion and a side portion continuous with the corner portion as viewed in a thickness direction of the adhesive sheet,
the inner peripheral surface is provided with a plurality of recesses, and
a density of the plurality of recesses decreases from a center of the side portion toward the corner portion.

14. A power conversion device comprising:
a main conversion circuit including the power semiconductor device according to claim 1, the main conversion circuit converting input power and outputting the converted power; and
a control circuit to output a control signal for controlling the main conversion circuit to the main conversion circuit.
